(19) United States
(12) Patent Application Publication
(10) Pub. No.: US 2011/0079878 A1
(43) Pub. Date: Apr. 7, 2011

(54) FERROELECTRIC CAPACITOR ENCAPSULATED WITH A HYDROGEN BARRIER

(75) Inventors: Rajni J. Aggarwal, Garland, TX (US); Scott R. Summerfelt, Garland, TX (US); Gul B. Basim, Plano, TX (US); Ted S. Moise, Dallas, TX (US)

(73) Assignee: TEXAS INSTRUMENTS INCORPORATED, Dallas, TX (US)

(21) Appl. No.: 12/890,219

(22) Filed: Sep. 24, 2010

Related U.S. Application Data
(60) Provisional application No. 61/249,478, filed on Oct. 7, 2009.

(51) Int. Cl. H01L 29/92; H01L 21/00

(52) U.S. Cl. 257/532; 438/3; 257/E29.342; 257/E21.001

(57) ABSTRACT

An integrated circuit containing a ferroelectric capacitor, an underlying hydrogen barrier, and an overlying hydrogen barrier layer. A method for forming an integrated circuit containing a ferroelectric capacitor, an underlying hydrogen barrier, and an overlying hydrogen barrier layer.

### CROSS-REFERENCE TO RELATED APPLICATIONS

This application claims the benefit of priority under U.S.C. §119(e) of U.S. Provisional Application 61/249,478 (Texas Instruments docket number TI-67739 PS, filed Oct. 7, 2009).

Moreover, this application is related to patent application Ser. No. ______ (Attorney Docket Number TI-68285, filed simultaneously with this application) entitled “Hydrogen Passivation of Integrated Circuits” and patent application Ser. No. 12/717,604 (Attorney Docket Number TI-67319, filed Mar. 4, 2010) entitled “Passivation of Integrated Circuits Containing Ferroelectric Capacitors and Hydrogen Barriers”. With their mention in this section, these patent applications are not admitted to be prior art with respect to the present invention.

### BACKGROUND

These embodiments relate to the field of integrated circuits. More particularly, these embodiments relate to protecting a ferroelectric capacitor from hydrogen degradation.

### DESCRIPTION OF THE VIEWS OF THE DRAWINGS

FIGS. 1A and 1B (Prior Art) and FIGS. 1C and 1D illustrate portions of integrated circuits.

FIGS. 2A through 2E illustrate steps in an integrated circuit process flow according to an embodiment.

FIGS. 3A and 3B illustrate the addition of a hydrogen releasing film according to another embodiment.

### DETAILED DESCRIPTION

The example embodiments are described with reference to the attached figures, wherein like reference numerals are used throughout the figures to designate similar or equivalent elements. The figures are not drawn to scale and they are provided merely to illustrate the example embodiments. Several aspects are described below with reference to example applications for illustration. It should be understood that numerous specific details, relationships, and methods are set forth to provide a full understanding of the example embodiments. One skilled in the relevant art, however, will readily recognize that the example embodiments can be practiced without one or more of the specific details or with other methods. In other instances, well-known structures or operations are not shown in detail to avoid obscuring the embodiment. The example embodiments are not limited by the illustrated ordering of acts or events, as some acts may occur in different orders and/or concurrently with other acts or events. Furthermore, not all illustrated acts or events are required to implement a methodology in accordance with the example embodiments.

Ferroelectric capacitors (FeCaps) are frequently used in integrated circuits to provide nonvolatile memory in devices such as Ferroelectric (“FRAM”) memories, high-k capacitors, piezoelectric devices, and pyroelectric devices. The construction of the ferroelectric capacitors may be integrated into a CMOS process flow after the formation of the transistor portion of the integrated circuit (e.g. after ‘front-end’ processing), but before the formation of the metallization or interconnection portion of the integrated circuit (e.g. before ‘back-end’ processing).

Many CMOS back-end processing steps include the use of hydrogen. For example, hydrogen may be used in the formation of trench etch-stop layers, etch clean, and copper sintering (e.g. heating). During these process steps, hydrogen may diffuse into the ferroelectric capacitor material, causing a degradation in the electrical properties of the device (such as degraded switched polarization of FRAM memory cells). To protect the FeCaps from degradation due to hydrogen, an electrically conductive hydrogen barrier layer may be used to form the bottom plate of an FeCap plus a hydrogen barrier film may be deposited over the FeCap.

The term “FeCap” refers to a ferroelectric capacitor. The ferroelectric dielectric of the FeCap may be composed of (but is not limited to) lead zirconate titanate (PZT).

The term “FeCap region” refers to an array of FeCaps having two or more FeCaps.

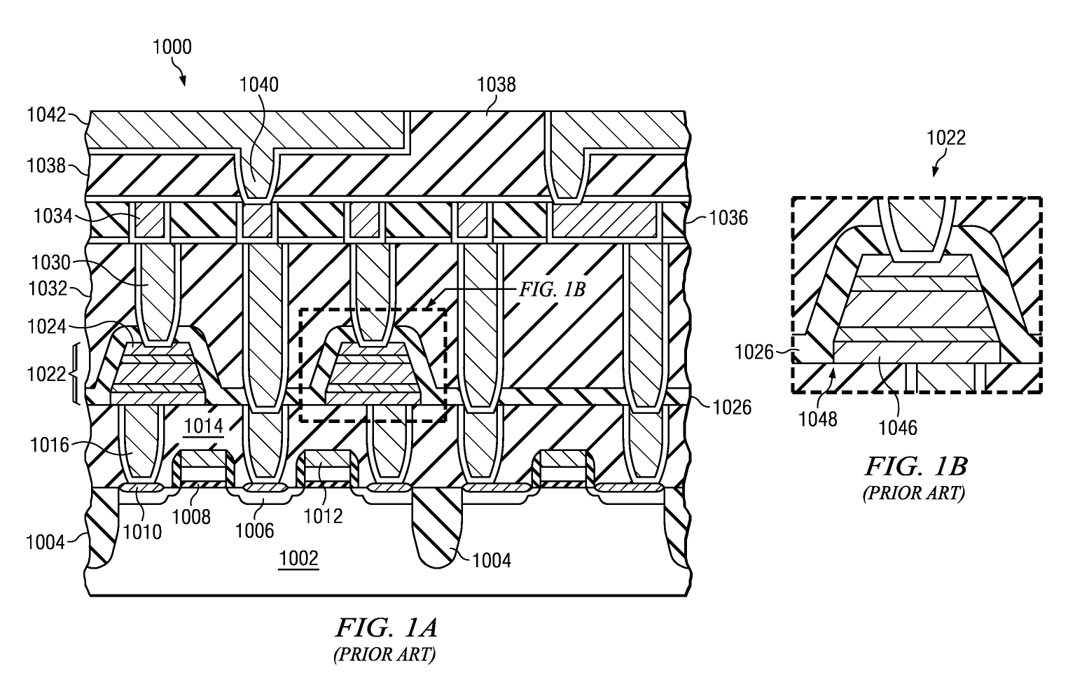

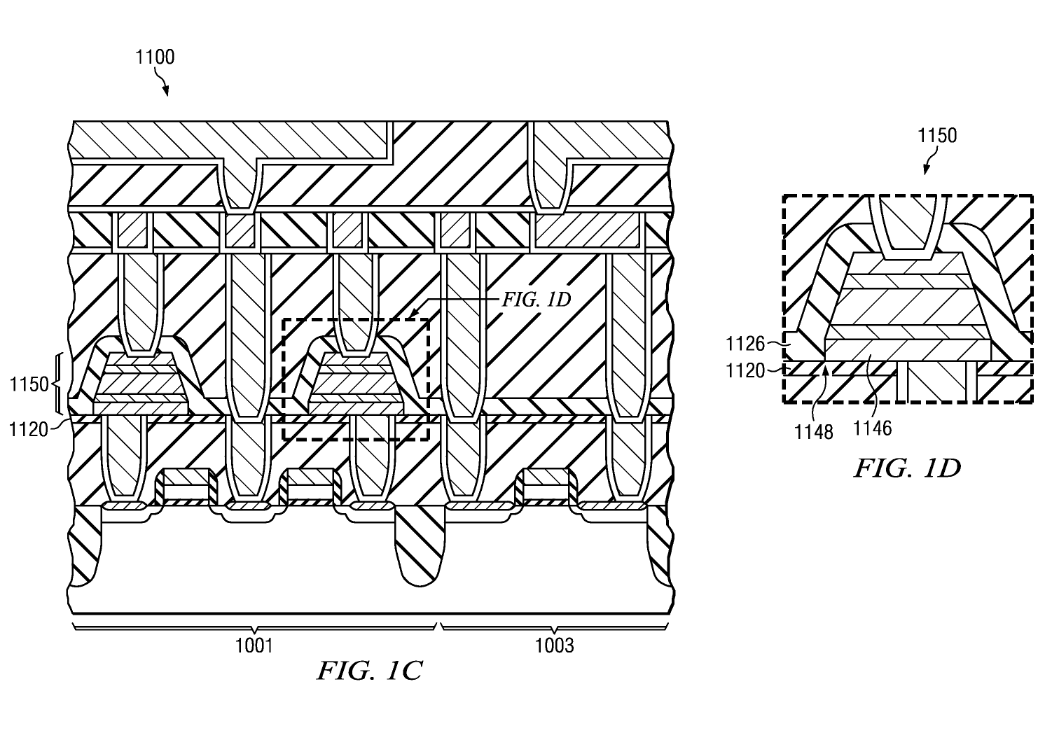

FIGS. 1A and 1B compare the encapsulation of a FeCap with hydrogen barrier layers to protect it from hydrogen degradation using conventional means (1000) to a fully encapsulated embodiment (1100) of the instant embodiment.

The integrated circuit (1000) containing an FeCap (1022) in FIG. 1A is formed on a substrate (1002) that contains shallow trench isolation (“STI”) regions (1004), transistor gates (1012), transistor gate dielectrics (1008), and transistor sources and drains (1006) (that may be silicided (1010)). The integrated circuit (1000) also contains a first pre-metal dielectric (“PMD”) layer (1014), contacts (1016), FeCaps (1022), and a hydrogen barrier film (1026). The hydrogen barrier film (1026) has been deposited over the FeCaps (1022) to protect the dielectric of the FeCap from hydrogen degradation.

A pre-metal dielectric (“PMD-2”) layer (1032) is deposited over the substrate (1002) containing FeCaps (1022). Second contacts (1030) are formed in the PMD-2 layer (1032) to make contact to the top plate (1024) of the FeCap (1022) and also to the transistor sources and drains (1006). A first level of metal interconnect (“met-1”) (1034) is formed within the first level of inter-metal dielectric (“IMD-1”) (1036) plus a second level of metal interconnect (“met-2”) (1042), and vias for the met-2 level (“via-2”) (1040) are formed within the second level of inter-metal dielectric (“IMD-2”) (1038). It is to be noted that either fewer or additional levels of metal interconnect and dielectric passivation may be used to complete the integrated circuit (1000).

A close up view of a FeCap (1022) is shown in FIG. 1B. The bottom plate (1046) of a FeCap (1022) may be composed of a conductive hydrogen barrier material such as, but not limited to, TiN, TiAlN, or TiAlON. Even with hydrogen barrier material as a bottom plate (1046) and hydrogen barrier film (1026) overlying the FeCap, hydrogen may still diffuse through seams (1048) that form between the bottom plate (1046) and the hydrogen barrier layer (1026). Hydrogen that diffuses through seams (1048) may degrade the electrical properties of the FeCap.

The integrated circuit structure (1100) in FIG. 1C has been formed according to an embodiment that prevents hydrogen diffusion through seams (1148) between the bottom plate (1146) and overlying hydrogen barrier layer (1126) is shown in the inset as shown in FIG. 1D. According to this embodiment, an underlying hydrogen barrier (1120) has been deposited over the integrated circuit (1100). The presence of the underlying hydrogen barrier (1120) under the FeCaps (1150) in the FeCap region (1001) may prevent hydrogen from diffusing through seams (1148), as shown in FIG. 1D.

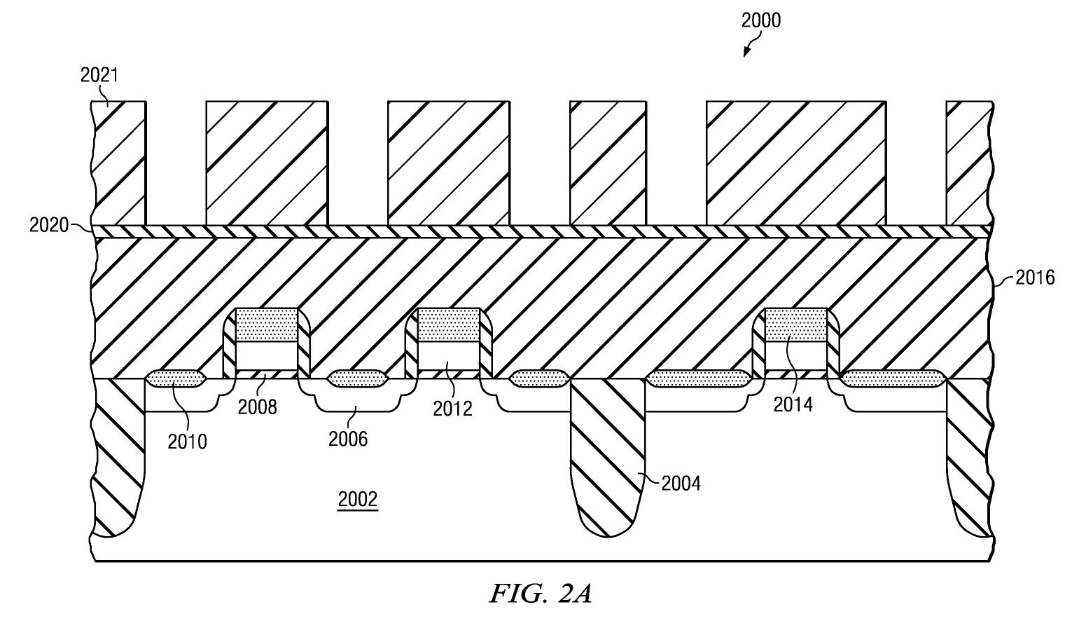

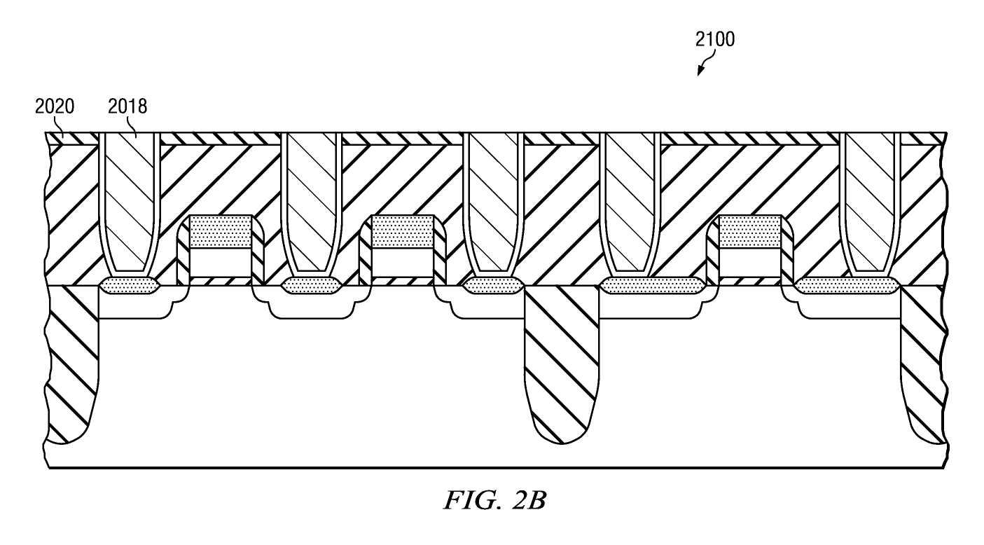

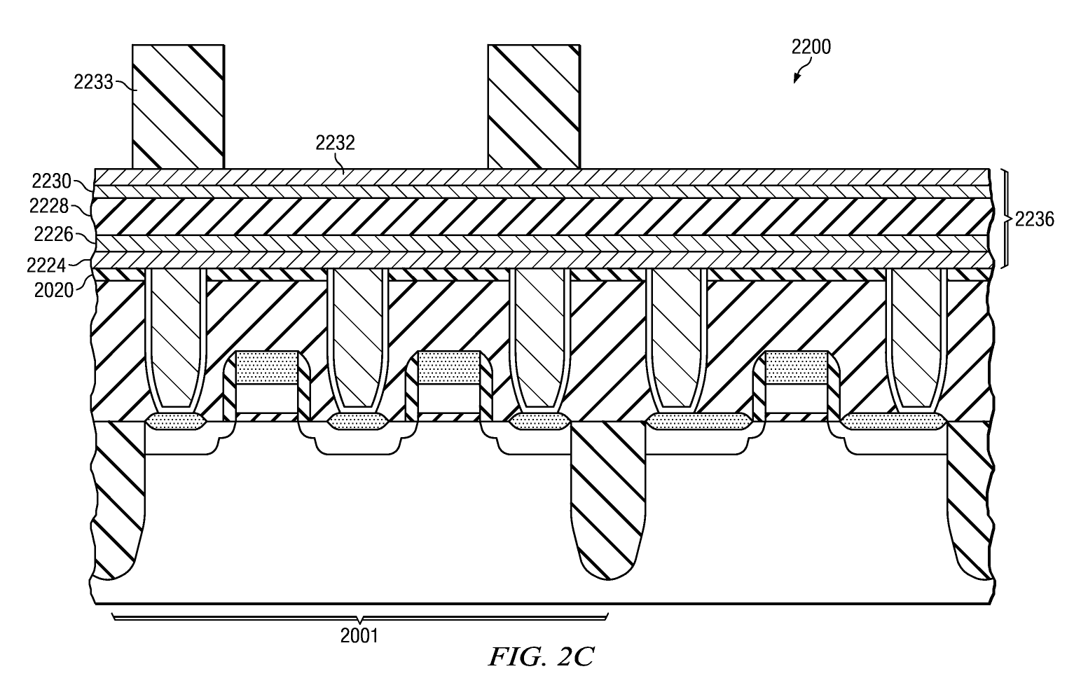

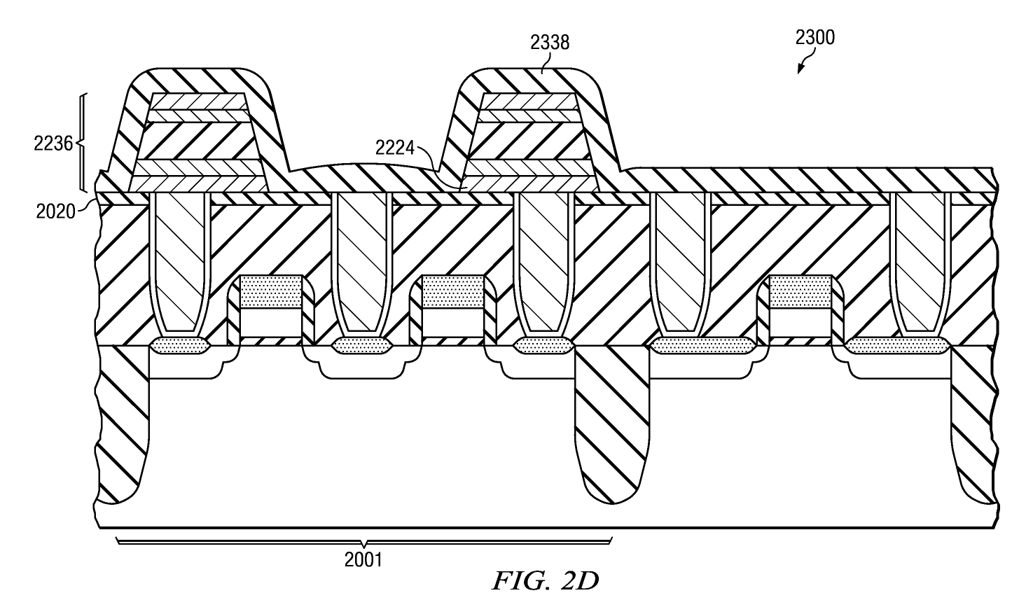

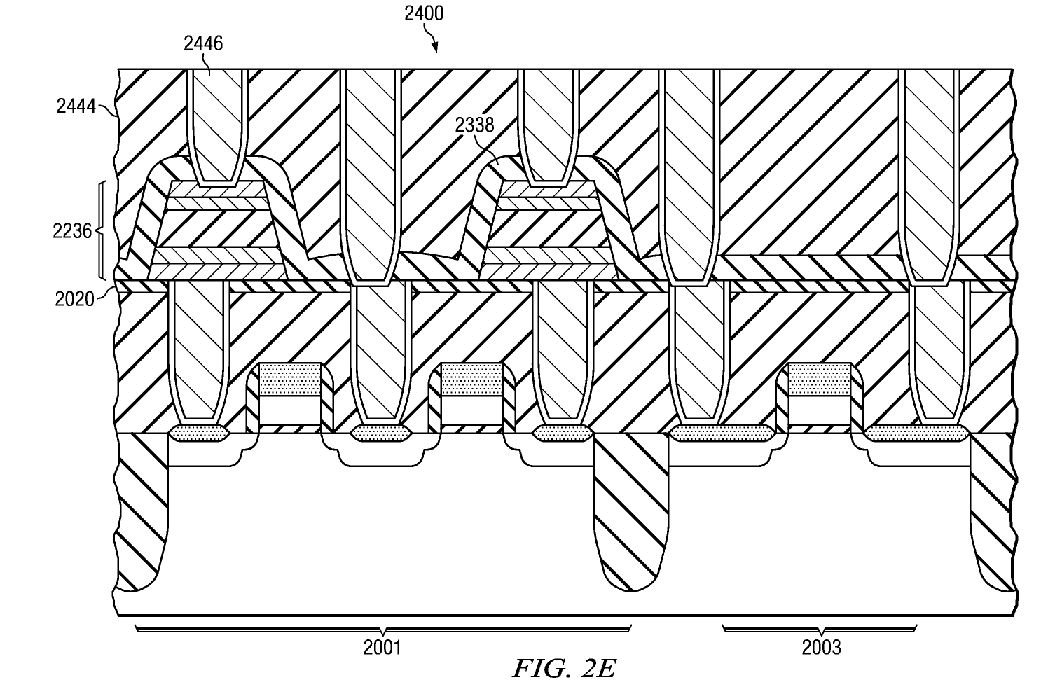

The manufacturing method for forming an integrated circuit according to an embodiment of the instant embodiment is illustrated in FIGS. 2A through 2D. The partially processed integrated circuit (2000) shown in FIG. 2A, is built on substrate (2002) and contains STIs (2004), transistor gate dielectrics (2008), transistor gates (2012), transistor sources and drains (2006), silicided source and drain diffusions (2010), silicided gates (2014), and PMD (2016). An underlying hydrogen barrier (2020) has been deposited over PMD (2016). The underlying hydrogen barrier may be formed of one or more dielectric thin films such as LPCVD SiN, low hydrogen PECVD SiN (known as “UV Sin”), AlOx, AlONx, SiNx, and SiNxHy. In the example embodiment shown in FIG. 2A, the underlying hydrogen barrier layer (2020) is SiNxHy. SiNxHy films typically contain hydrogen in the form of Si—H and N—H bonds. One example process for the underlying hydrogen barrier SiNxHy film (2020) is the formation of a low Si—H bond material using plasma enhanced chemical vapor deposition (“PECVD”) with a relatively high nitrogen (N2) gas flow and relatively low ammonia (NH3) flow. This example process is shown infra in Table 1. It is to be noted that alternative processes, such as high density plasma (HDP), may be used to produce the SiNxHy underlying hydrogen barrier of this example embodiment.

TABLE 1

| Process Variable | VALUE | UNITS |
|---|---|---|
| Deposition | PECVD | — |
| High Frequency Power | 700 | watts |
| Low Frequency Power | 100 | watts |
| Pressure | 2.25 | Torr |
| Temperature | 400 | C. |
| SiH4 | 150 | sccm |
| N2 | 1400 | sccm |
| NH3 | 750 | sccm |

As shown in FIG. 2A, a photoresist contact pattern (2021) has been formed over the integrated circuit (2000) to expose the locations where the PMD (2016) is etched before the formation of electrical contacts within the PMD (2016). FIG. 2B shows the integrated circuit (2100) after the contacts (2018) have been formed, using any well known processing technique, through the PMD (2016) and the underlying hydrogen barrier SiNxHy film (2020).

FIG. 2C shows example steps in the formation of the FeCaps (2236). The layers that are deposited to form the FeCap (2236) include bottom (2224) and top (2232) capacitor plates that are formed from a conductive hydrogen barrier material such as TiN, TiAlN, or TiAlON. The FeCap (2236) also includes top (2230) and bottom (2226) capacitor electrodes formed from a conductive material such as Pt, Pd, PdOx, IrPt alloys, Au, Ru, RuOx, (Ba, Sr, PB)RuO3, (Ba,Sr)RuO3, or LaNiO3. In addition, the FeCap (2236) includes a ferroelectric dielectric material (2228) such as (but not limited to) PZT. A FeCap photoresist pattern (2233) has been formed over the integrated circuit (2200) in preparation for etching the FeCap films (2232), (2230), (2228), (2226), (2224) to form FeCaps (2236) within the FeCap region (2001), as shown in FIG. 2D.

FIG. 2D shows the integrated circuit (2300) after the FeCaps (2236) have been etched—using the underlying hydrogen barrier (2020) as an etch stop. Next, an overlying hydrogen diffusion barrier layer (2338) is deposited on top of the FeCap (2236) to completely encapsulate the FeCap (2236) with hydrogen barrier materials. The overlying hydrogen barrier layer (2338) may be composed of one or more hydrogen barrier films such as AlOx, AlONx, SiNx, or SiNxHy. In FIG. 2D, the overlying hydrogen barrier layer (2338) is shown to be one layer but it may be composed of one or more hydrogen barrier layers.

As described in copending U.S. patent application Ser. No. 12/717,604 incorporated supra, hydrogen barrier films (2020) and (2338) may be patterned and etched from over the transistors that are in periphery logic regions (2003) (see FIG. 2E) to enable the hydrogen passivation of the interface states in the circuitry of the periphery logic region (2003) and thereby narrow the transistor threshold voltage (“Vₜ”) distributions.

In another example embodiment, the overlying hydrogen barrier layer (2338) may be composed of two hydrogen diffusion barrier films. The first overlying hydrogen barrier film may be nitrided aluminum oxide (“AlONx”) that may be deposited using physical vapor deposition (“PVD”) or atomic layer deposition (“ALD”). The nitridation of the AlOx to improve the hydrogen barrier properties may be accomplished by exposing the AlOx to a nitrogen-containing plasma, or by annealing the AlOx at about 400C in a nitrogen containing ambient. The second overlying hydrogen barrier film may be SiNxHy that is formed using the same PECVD process as the underlying hydrogen barrier layer described in Table 1 supra.

FIG. 2E shows integrated circuit (2400) after additional processing adds a second layer of PMD (2444) and second contacts (2446) (that are possibly formed by a process that includes the use of the overlying hydrogen barrier layer (2338) as an etch stop). Further interconnect layers and passivation may then be added to complete integrated circuit (2400).

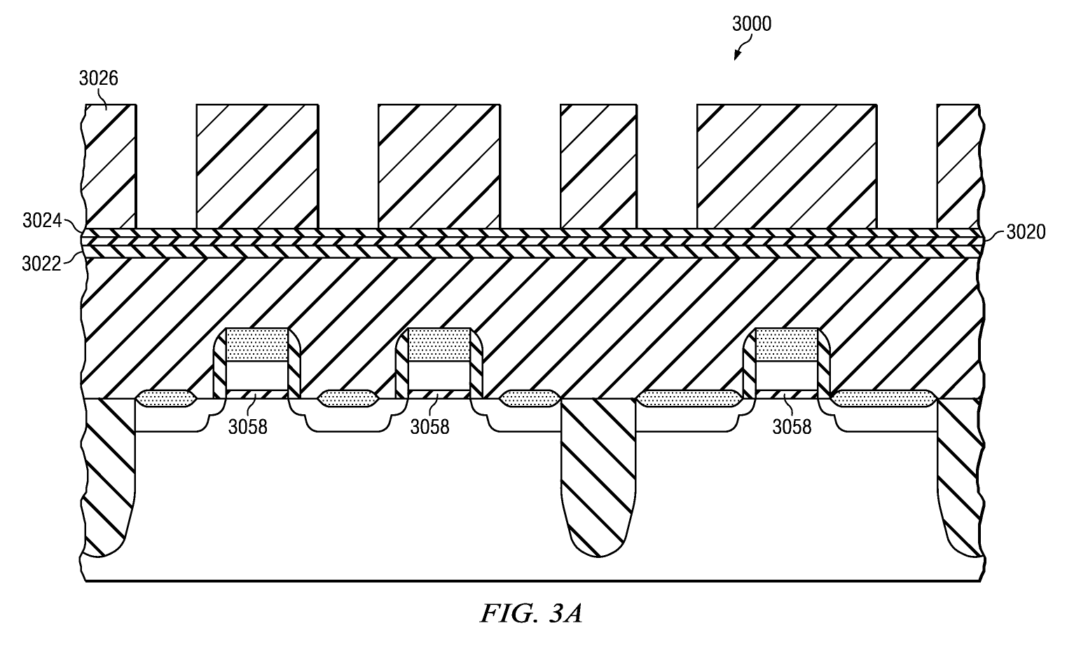

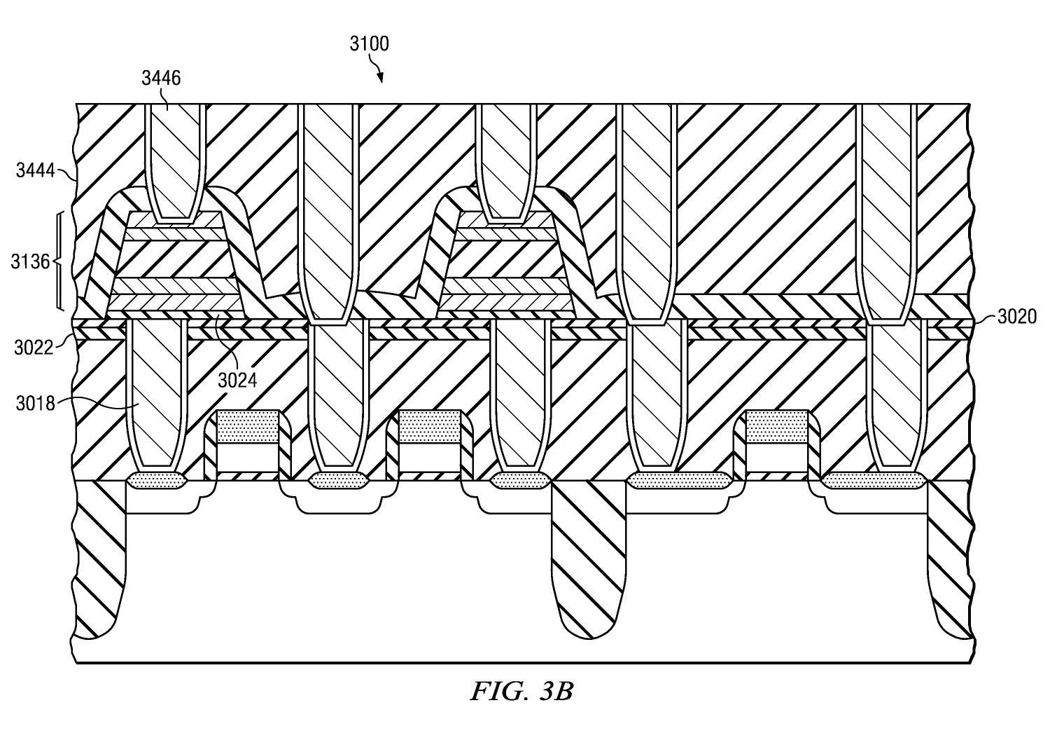

Another embodiment is illustrated in FIGS. 3A and 3B. The underlying hydrogen barrier layer (3020) that protects the FeCaps from the hydrogen that may diffuse through the seams between the encapsulating hydrogen barrier layers may also prevent hydrogen from diffusing to the interface (3058) and thereby passivating the interface states. An inadequate hydrogen passivation of the interface states may result in decreased manufacturing yield due to widened CMOS transistor Vₜ distributions, Vₜ instability, and degraded analog transistor characteristics.

As described in copending U.S. patent application Ser. No.______ incorporated supra, a hydrogen releasing film (3022) may be formed under the underlying hydrogen barrier film (3020) in the integrated circuit (3000). The hydrogen releasing layer (3022) may be a SiNxHy film that is deposited using HDP under process conditions, such as those shown in Table 2 supra, to form a SiNxHy film (3022) with a high concentration of Si—H bonds.

TABLE 2

| Process Variable | VALUE | UNITS |
|---|---|---|
| Deposition | HDP | — |
| Low Frequency Power | 1850 | watts |
| Pressure | 15 | mTorr |
| Temperature | 400 | C. |
| SiH4 | 40 | sccm |
| N2 | 400 | sccm |
| Ar | 250 | sccm |

Generally, Si—H bonds are of a lower bond energy (e.g. about 3.34 eV) than N—H bonds (e.g. about 4.05 eV). Therefore, Si—H bonds tend to dissociate during thermal processing steps (such as copper anneals that usually release hydrogen). During back-end thermal steps (such as the copper anneals) hydrogen may be released from this hydrogen releasing film (3022) and may diffuse into the interface (3058) and then passivate the interface states and crystalline defects. However, the underlying hydrogen barrier (3020) of this embodiment may prevent this released hydrogen from diffusing upwards and subsequently degrading the FeCap. The underlying hydrogen barrier film (3020) that is located on top of the hydrogen releasing film (3022) may also prevent the degradation of the passivation by preventing hydrogen from diffusing away from the interface.

Instead of a hydrogen-releasing film (3022) of FIGS. 3A and 3B, a deuterium releasing film may be used for the passivation of the interface states and the crystal defects. Deuterium is more expensive than hydrogen, but the deuterium-silicon bonds in deuterium-passivated interface states are stronger than hydrogen-silicon bonds in hydrogen-passivated interface states. Therefore, the Vₜ's of transistors on deuterium passivated wafers are typically more stable over time than the Ws of transistors on hydrogen passivated wafers. Similar to the hydrogen releasing film, the deuterium in a deuterium releasing film is predominately bonded to silicon (Si—D). Because Si—D bonds are lower energy than nitrogen to deuterium (N—D) bonds, the Si—D bonds may dissociate during high temperature anneals, thereby providing deuterium atoms for the passivation of the interface states.

An optional oxide capping layer (3024) may be deposited on top of the underlying hydrogen barrier (3020) to prevent photoresist from coming into contact with the SiNxHy underlying hydrogen barrier (3020). When the SiNxHy film is formed with NH₃ (see Table 1, supra), residual NH₃ may remain in the film and may react with the contact photoresist (3026), making the contact photoresist (3026) difficult develop and also difficult to be removed later in the fabrication process. In the embodiment shown in FIG. 3A, the contact photoresist (3026) is formed on the optional oxide capping layer.

FIG. 3B shows an integrated circuit (3100) after first contacts (3018) have been formed and contact photoresist pattern (3026) removed. Also shown are the FeCaps (3136), PMD-2 (3444) and second contacts (3446). Additional processing to add other interconnects and dielectric layers may be performed to complete the integrated circuit.

While various example embodiments have been described above, it should be understood that they have been presented by way of example only and not limitation. Numerous changes to the disclosed embodiments can be made in accordance with the disclosure herein without departing from the spirit or scope of the example embodiments. Thus, the breadth and scope of the example embodiments should not be limited. Rather, the scope of the example embodiments should be defined in accordance with the following claims and their equivalents.

What is claimed is:

1. An integrated circuit, comprising:
an FeCap;
an underlying hydrogen barrier coupled to a bottom surface of said FeCap; and
an overlying hydrogen barrier layer in contact with a portion of a top surface of said underlying hydrogen barrier.

2. The integrated circuit of claim 1 wherein said overlying hydrogen barrier layer is also coupled to side and top surfaces of said FeCap.

3. The integrated circuit of claim 1 wherein said underlying hydrogen barrier is in contact with a PMD layer of said integrated circuit.

4. The integrated circuit of claim 1 wherein said underlying hydrogen barrier is selected from the group consisting of
AlO,
AlON,
SiNx,
SiNxHy, and
any combination thereof.

5. The integrated circuit of claim 1 wherein said overlying hydrogen barrier layer is comprised of a nitrided AlO film and a SiNxHy film.

6. The integrated circuit of claim 1 wherein said overlying hydrogen barrier layer is a SiNxHy film.

7. The integrated circuit of claim 1 wherein said underlying hydrogen barrier is in contact with a bottom plate of said FeCap, and said overlying hydrogen barrier layer is in contact with a top plate of said FeCap.

8. An integrated circuit, comprising:
an FeCap;
an underlying hydrogen barrier coupled to a bottom surface of said FeCap;
a hydrogen releasing film coupled to a bottom surface of said underlying hydrogen barrier; and
an overlying hydrogen barrier layer in contact with a portion of said underlying hydrogen barrier.

9. The integrated circuit of claim 8 wherein said hydrogen releasing film is in contact with said bottom surface of said underlying hydrogen barrier.

10. The integrated circuit of claim 8 wherein an oxide capping layer is coupled between said underlying hydrogen barrier and said bottom surface of said FeCap.

11. The integrated circuit of claim 10 wherein an oxide capping layer is in contact with a bottom plate of said FeCap, and said overlying hydrogen barrier layer is in contact with a top plate of said FeCap.

12. The integrated circuit of claim 8 wherein said underlying hydrogen barrier is selected from the group consisting of
AlO,
AlON,
SiNx,
SiNxHy, and
any combination thereof.

13. The integrated circuit of claim 8 wherein said hydrogen releasing film includes SiNxHy with a higher concentration of Si—H bonds than N—H bonds.

14. An integrated circuit, comprising:
an FeCap;
an underlying hydrogen barrier coupled to a bottom surface of said FeCap;
a deuterium releasing film coupled to a bottom surface of said underlying hydrogen barrier; and
an overlying hydrogen barrier layer in contact with a portion of said underlying hydrogen barrier.

15. The integrated circuit of claim 14 wherein an oxide capping layer is coupled between said underlying hydrogen barrier and said bottom surface of said FeCap.

16. The integrated circuit of claim 14 wherein said deuterium releasing film includes SiNxDy with a higher concentration of Si—D bonds than N—D bonds.

17. A process of forming an integrated circuit, comprising:
providing a partially processed integrated circuit having a PMD layer;
depositing an underlying hydrogen barrier on said PMD layer; and
forming a FeCap over said underlying hydrogen barrier.

18. The process of claim 17 further comprising a step of depositing an oxide capping layer over said underlying hydrogen barrier prior to said step of forming a FeCap.

19. The process of claim 17 further comprising a step of depositing at least one of a hydrogen releasing film and a deuterium releasing film prior to said step of depositing said underlying hydrogen barrier.

20. The process of claim 17 further comprising a step of depositing an overlying hydrogen barrier layer on said integrated circuit subsequent to said step of forming a FeCap.
